(19) United States
(12) Patent Application Publication
(10) Pub. No.: US 2026/0157033 A1
(43) Pub. Date: Jun. 4, 2026

(54) LIGHT-EMITTING ELEMENT, DISPLAY DEVICE, AND LIGHT-EMITTING ELEMENT MANUFACTURING METHOD

(71) Applicant: Sharp Display Technology Corporation, Kameyama City, Mie (JP)

(72) Inventors: Haijun LI, Kameyama City, Mie (JP); Tokiyoshi UMEDA, Kameyama City, Mie (JP); Yuto TSUKAMOTO, Kameyama City, Mie (JP); Nobuo SAITO, Kameyama City, Mie (JP)

(21) Appl. No.: 18/866,522

(22) PCT Filed: Jun. 30, 2022
(86) PCT No.: PCT/JP2022/026284

§ 371 Date: Nov. 15, 2024

(51) Int. Cl. H10K 50/858; H10K 50/844; H10K 59/35

(52) U.S. Cl. CPC H10K 50/858; H10K 50/844; H10K 59/35

(57) ABSTRACT

A light-emitting element includes: a first electrode; a light-emitting layer located above the first electrode; a second electrode located above the light-emitting layer; a capping layer located on the second electrode and including at least one of an amphiphilic material and a hydrophilic material; and a sealing layer located on the capping layer.

### TECHNICAL FIELD

The disclosure relates to a light-emitting element, a display device, and a method for manufacturing a light-emitting element.

### BACKGROUND ART

PTL 1 discloses an organic EL element having a desiccant capable of suppressing the growth of dark spots by providing a water-capturing medium layer for chemically capturing water on a water-capturing medium holding layer.

### CITATION LIST

### Patent Literature

PTL 1: JP 2003-264061 A (published on Sep. 19, 2003)

### SUMMARY

### Technical Problem

In PTL 1, a product resulting from a chemical reaction between the water-capturing medium layer and water may cause deterioration of the organic EL element.

### Solution to Problem

A light-emitting element according to an aspect of the disclosure includes: a first electrode; a light-emitting layer located above the first electrode; a second electrode located above the light-emitting layer; a capping layer located on the second electrode, the capping layer including at least one of an amphiphilic material and a hydrophilic material; and a sealing layer located on the capping layer.

A method for manufacturing a light-emitting element according to an aspect of the disclosure includes: forming a light-emitting diode including a first electrode, a light-emitting layer, and a second electrode that is light-transmissive; forming a capping layer including at least one of an amphiphilic material and a hydrophilic material on the second electrode; and forming a sealing layer on the capping layer.

### Advantageous Effects of Disclosure

According to an aspect of the disclosure, it is possible to prevent or delay deterioration of a light-emitting element.

### BRIEF DESCRIPTION OF DRAWINGS

FIG. 1 is a cross-sectional view illustrating a configuration example of a light-emitting element according to an embodiment of the disclosure.

FIG. 2 is a flowchart illustrating an example of a method for manufacturing the light-emitting element illustrated in FIG. 1.

FIG. 3 is a cross-sectional view illustrating penetration of water into a configuration example of the light-emitting element according to the embodiment of the disclosure.

FIG. 4 is a cross-sectional view illustrating penetration of water into another configuration example of the light-emitting element according to the embodiment of the disclosure.

FIG. 5 is a cross-sectional view illustrating still another configuration example of the light-emitting element according to the embodiment of the disclosure.

FIG. 6 is a cross-sectional view illustrating still another configuration example of the light-emitting element according to the embodiment of the disclosure.

FIG. 7 is a cross-sectional view illustrating still another configuration example of the light-emitting element according to the embodiment of the disclosure.

FIG. 8 is a cross-sectional view illustrating still another configuration example of the light-emitting element according to the embodiment of the disclosure.

FIG. 9 is a plan view illustrating a configuration example of a display device according to an embodiment of the disclosure.

FIG. 10 is a cross-sectional view illustrating a configuration example of the display device according to the embodiment of the disclosure.

FIG. 11 is a cross-sectional view illustrating another configuration example of the display device according to the embodiment of the disclosure.

### DESCRIPTION OF EMBODIMENTS

### First Embodiment

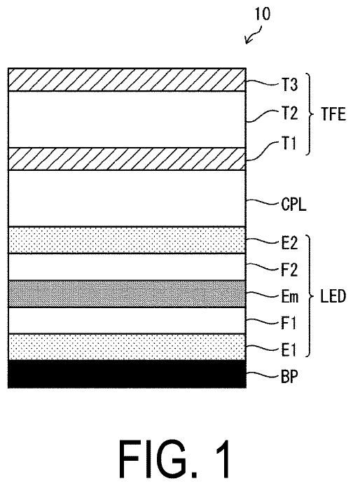

FIG. 1 is a cross-sectional view illustrating a configuration example of a light-emitting element according to an embodiment of the disclosure. As illustrated in FIG. 1, a light-emitting element 10 according to the present embodiment includes a light-emitting diode LED including a first electrode E1, a light-emitting layer Em located above the first electrode E1, and a second electrode E2 located above the light-emitting layer Em, and also includes a capping layer CPL located on the second electrode E2 and a sealing layer TFE located on the capping layer CPL. The light-emitting element 10 may further include a substrate BP on which the first electrode E1 is located. The light-emitting diode LED may include one or both of a charge function layer F1 located between the first electrode E1 and the light-emitting layer Em and a charge function layer F2 located between the second electrode E2 and the light-emitting layer Em. Each of the charge function layers F1 and F2 may include any one or more of a charge injection layer, a charge transport layer, and a charge blocking layer.

One of the first electrode E1 and the second electrode E2 is an anode and the other is a cathode. The first electrode E1 is a reflective electrode that reflects light, the second electrode E2 is a transparent electrode that is light-transmissive, and the light-emitting element 10 is of a top emission type that emits light upward. The transparent electrode is composed of a light-transmissive metal oxide such as indium gallium zinc oxide (InGaZnO) or a metal thin film such as a silver alloy. The transparent electrode is likely to react with water and deteriorate. For example, the first electrode E1 is a light-reflective anode, and the second electrode E2 is a light-transmissive cathode. The light-emitting layer Em is an organic light-emitting layer including an organic light-emitting material, or a quantum dot light-emitting layer including a quantum dot as a light-emitting material. The organic light-emitting material and the quantum dot are likely to react with water and deteriorate.

The capping layer CPL is provided for the purpose of improving a light extraction efficiency from the light-emitting element 10 by refractive index adjustment. In addition, the capping layer CPL according to the disclosure is configured to include a material having a hydrophilic group, that is, at least one of an amphiphilic material and a hydrophilic material for the purpose of capturing water 20 that has penetrated. The amphiphilic material has both hydrophobic and hydrophilic groups and is also referred to as a “surfactant” or “emulsifier”. The hydrophilic material has a hydrophilic group and is also referred to as a “water-absorbing material”, “water-holding material”, “hygroscopic material”, or “moisture-retaining material”.

The capping layer CPL may be thicker than the second electrode E2 and thinner than a sealing layer TFE. The sealing layer TFE may have a multilayer structure including, for example, inorganic sealing films T1 and T3 and an organic sealing film T2 located between the inorganic sealing films T1 and T3.

### Manufacturing Method

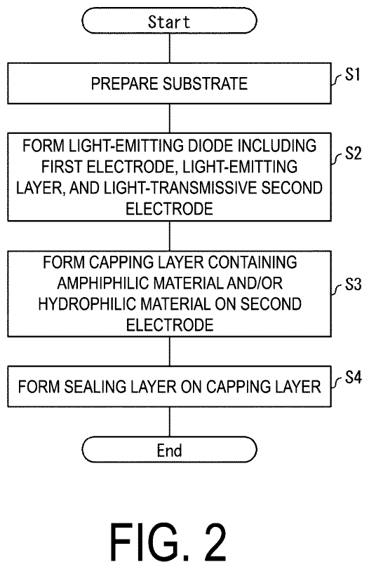

FIG. 2 is a flowchart illustrating an example of a method for manufacturing the light-emitting element illustrated in FIG. 1. As illustrated in FIG. 2, first, the substrate BP is prepared (step S1), and the light-emitting diode LED including the first electrode E1, the light-emitting layer Em, and the light-transmissive second electrode E2 is formed on the substrate BP (step S2). Subsequently, the capping layer CPL is formed on the second electrode E2 (step S3), and the sealing layer TFE is formed on the capping layer CPL (step S4).

In step S3, the capping layer CPL is formed by vapor deposition or coating. Steps S1, S2, and S4 may be performed in a known manner.

### Capping Layer of Comparative Example

A capping layer of a comparative example is composed of a hydrophobic material and includes neither an amphiphilic material nor a hydrophilic material in such a manner that the capping layer does not adsorb water. The capping layer of the comparative example cannot capture water. For this reason, in a light-emitting element including the capping layer of the comparative example, once water enters the inside through the sealing layer, the water passes through the capping layer and reaches the light-transmissive second electrode and the light-emitting layer to deteriorate the light-emitting element. Due to this, in the comparative example, issues such as a decrease in reliability of the light-emitting element, occurrence of defects, a decrease in light extraction efficiency, and a decrease in internal quantum efficiency are likely to occur. The defects include unevenness, discoloration, black spots, and the like.

### Configuration Example 1 of Capping Layer

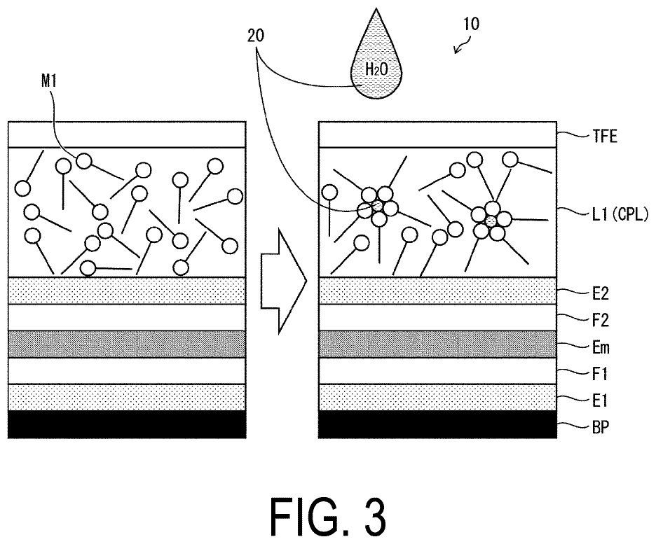

FIG. 3 is a cross-sectional view illustrating penetration of water into a configuration example of the light-emitting element according to the embodiment of the disclosure. Note that FIG. 3 is a view focusing on the capping layer CPL, and does not illustrate an actual relationship of layer thicknesses. As illustrated in FIG. 3, the capping layer CPL may include an amphiphilic material M1, and may be composed of a single layer of an amphiphilic layer L1 including the amphiphilic material M1, as an example. When the water 20 penetrates from the outside to the inside of the light-emitting element 10, the water 20 reaches the amphiphilic layer L1 in the capping layer CPL through a defect of the sealing layer TFE. In the amphiphilic layer L1, the amphiphilic material M1 surrounds the water 20 with hydrophilic groups facing the water 20 and hydrophobic groups facing the opposite side. As a result, the water 20 is hydrogen-bonded to the hydrophilic groups of the amphiphilic material M1 and captured. The capturing in the amphiphilic layer L1 prevents or delays penetration of the water 20 into layers below the capping layer CPL.

Accordingly, as compared with the configuration of the comparative example, according to the present configuration example, even when the water 20 penetrates to the inside of the light-emitting element 10 through the sealing layer TFE, it is possible to prevent or delay deterioration of the second electrode E2 and the light-emitting layer Em due to the water 20. That is, it is possible to prevent or delay deterioration of the light-emitting element 10.

The amphiphilic material M1 may have, as a hydrophobic group, at least one selected from the group consisting of a linear alkyl group having 8 or more and 18 or less carbon atoms, a branched alkyl group having 8 or more and 18 or less carbon atoms, an alkylbenzene group having 6 or more and 16 or less carbon atoms, an alkylnaphthalene group, a perfluoroalkyl group having 4 or more and 9 or less carbon atoms, a polypropylene oxide group, and a polysiloxane group. The amphiphilic material M1 may have, as a hydrophilic group, at least one selected from the group consisting of a hydroxyl group, a phosphate group, a carboxyl group, a sulfate group, a sulfo group, a pyridium group, a quaternary ammonium group, a fatty acid group, a primary alcohol group, a secondary alcohol group, a tertiary alcohol group, an ether group, a polyethylene oxide group, an amide group, and an amino group.

The amphiphilic material M1 may include a material in which one or more hydrogens in a hydrophobic material are substituted with hydrophilic groups. The amphiphilic material M1 may include, for example, a material in which a hydrogen in at least one selected from the group consisting of a hydrophobic hole injection and transport material, a hydrophobic electron transport material, and a hydrophobic organic light-emitting material is substituted with a hydrophilic group. The hole injection and transport material is a material capable of exhibiting one or both of a hole injecting property and a hole transporting property. The hydrophobic hole injection and transport material includes a carbazole derivative, a triarylamine derivative, a dibenzothiophene derivative, and the like. The hydrophobic electron transport material includes a phenanthrene derivative, a silole derivative, a tris(8-quinolinolato)aluminum derivative, and the like. The organic light-emitting material includes an acene (polyacene) derivative, a quinacridone derivative, a bisstyrylbenzene derivative, and the like. The organic light-emitting material also includes a polymer-based polyphenylene vinylene derivative, a polythiophene derivative, a polyfluorene derivative, and the like.

As examples of the hydrophobic electron transport material, chemical formulas (1) to (4) of Alq₃, BCP, t-Bu-PBD, and a silole derivative are indicated below.

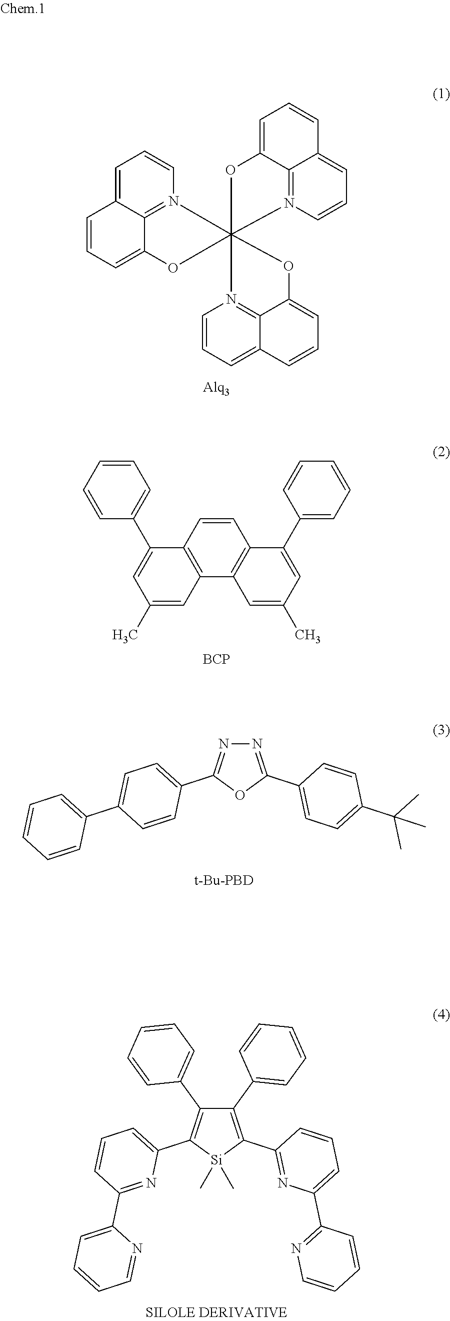

As examples of the hydrophobic hole injection material, chemical formulas (5) to (7) of CuPc, PEDOT/PSS, and m-TDATA are indicated below.

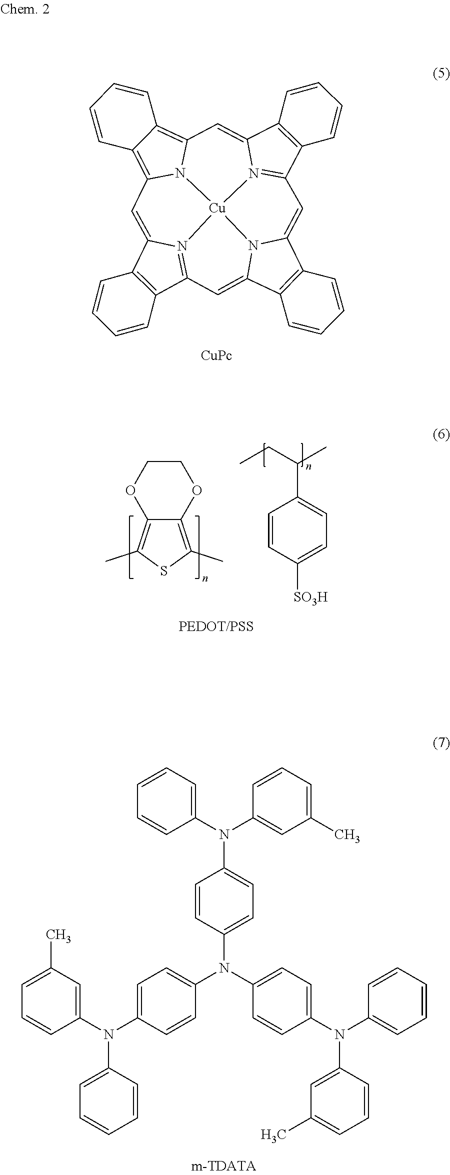

As examples of the hydrophobic hole transport material, chemical formulas (8) to (10) of TPD, α-NPD, and TCTA are indicated below.

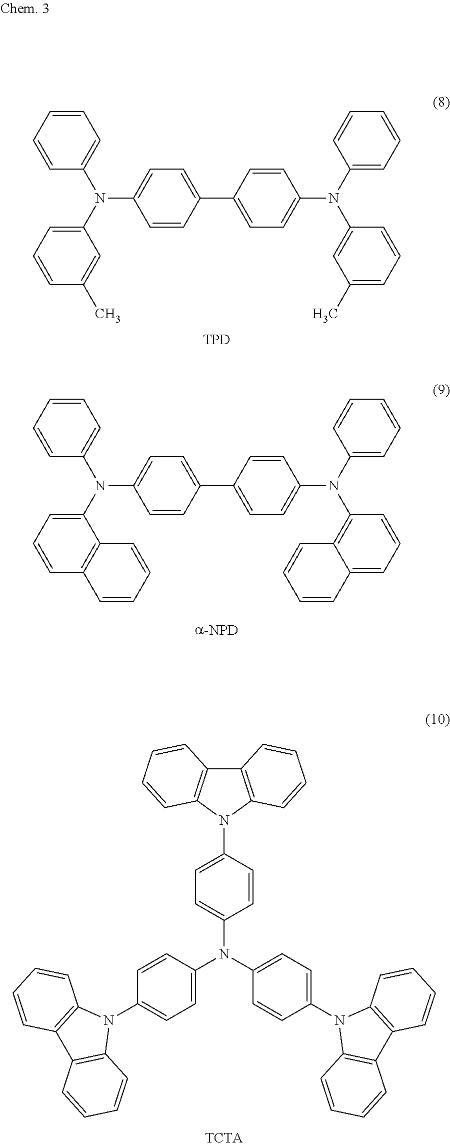 [SMILES: Cc1cccc(N(c2ccccc2)c2ccc(-c3ccc(N(c4ccccc4)c4cccc(C)c4)cc3)cc2)c1 ; "TPD" ; c1ccc(N(c2ccc(-c3ccc(N(c4ccccc4)c4cccc5ccccc45)cc3)cc2)c2cccc3ccccc23)cc1 ; "a-NPD" ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

As examples of the hydrophobic organic light-emitting material, chemical formulas (11) to (17) of a bisstyrylbenzene derivative, Alq₃, Zn-PBO, rubrene, dimethylquinacridone, DMQ, and DCM2 are indicated below.

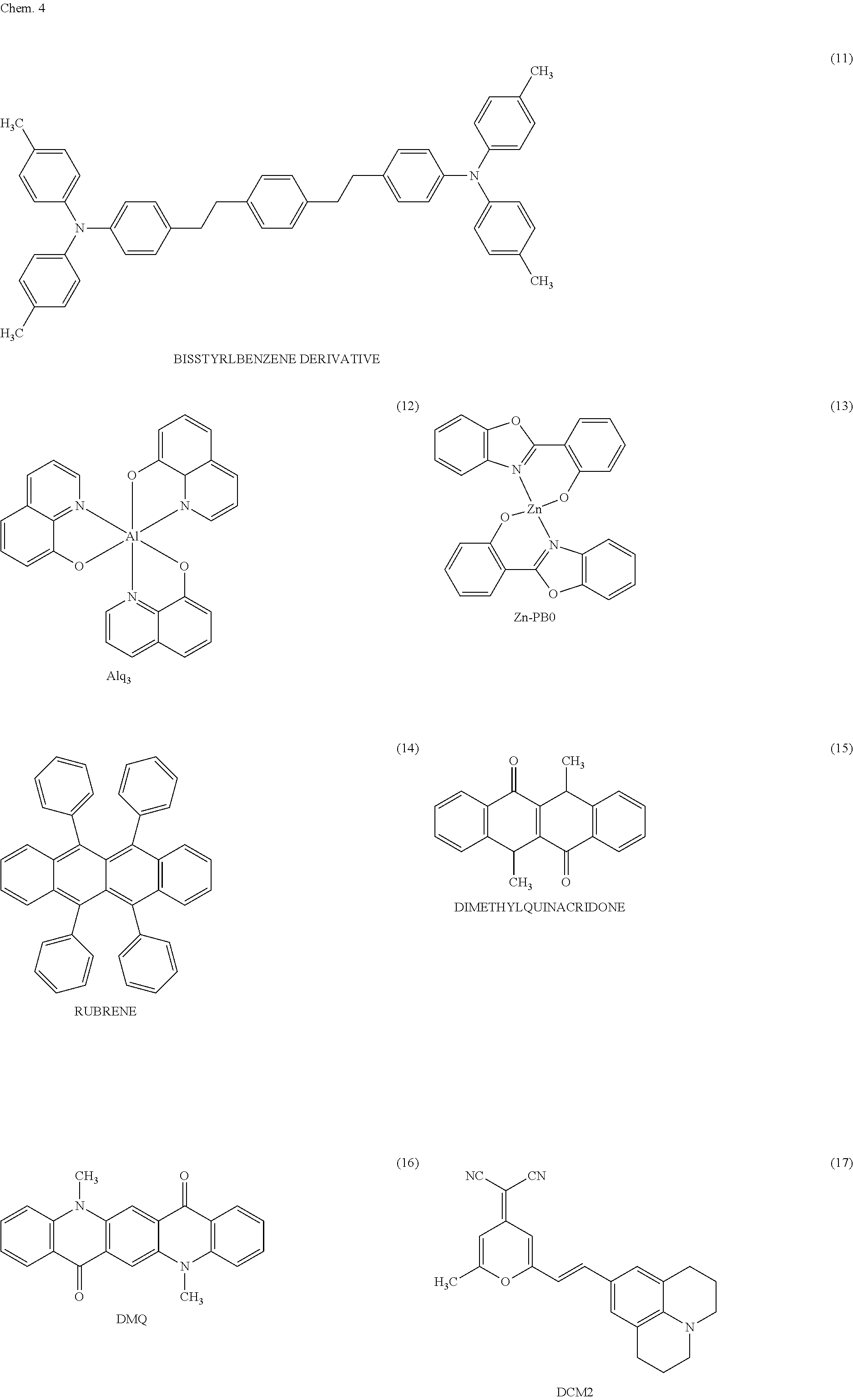

As examples of a phosphorescent material among the hydrophobic organic light-emitting materials, chemical formulas (18) to (20) of Flrpic, Ir(ppy)₃, and (ppy)₂Ir(acac) are indicated below.

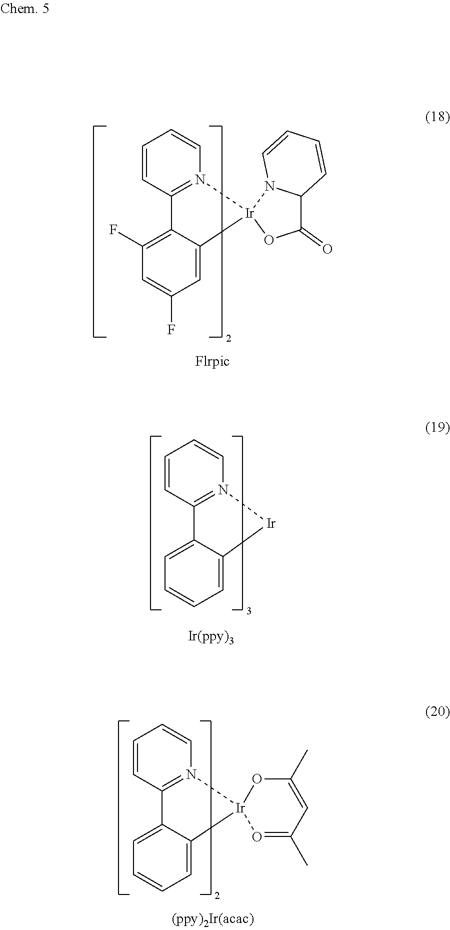

As examples of a polymer among the hydrophobic organic light-emitting materials, chemical formulas (21) to (23) of PPV, MEH-PPV, and PF are indicated below.

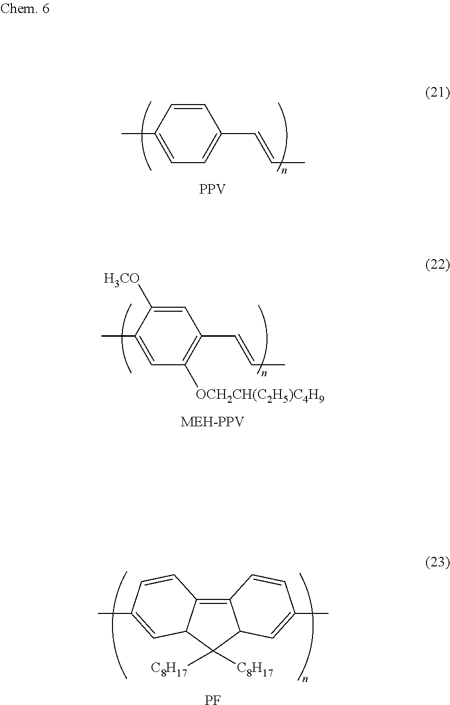

The amphiphilic material M1 may include at least one selected from the group consisting of alkylcarboxylic acid, phosphatidylcholine, and fluorescein. Chemical formulas (24) to (26) of alkylcarboxylic acid, phosphatidylcholine, and fluorescein are indicated below.

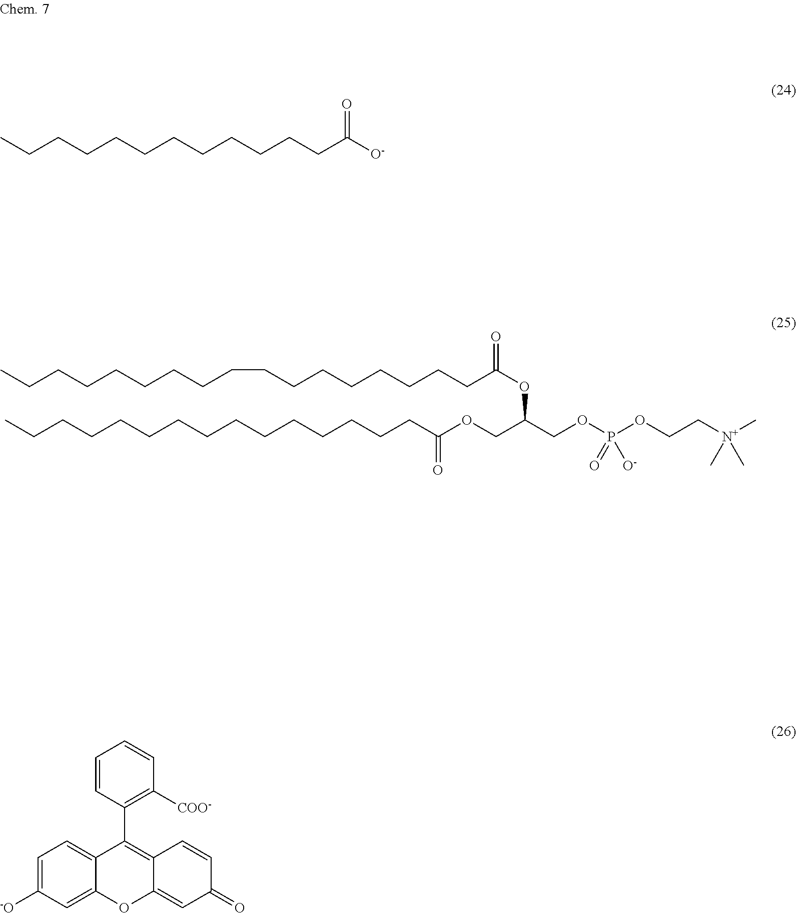

### Configuration Example 2 of Capping Layer

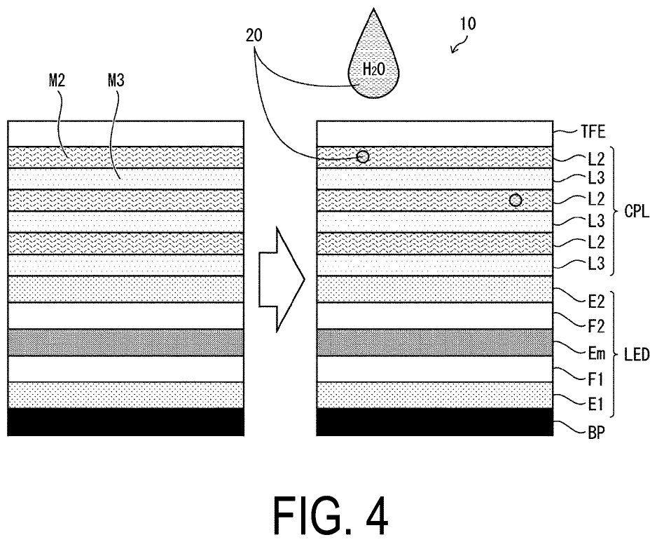

FIG. 4 is a cross-sectional view illustrating penetration of water into another configuration example of the light-emitting element according to the embodiment of the disclosure. Note that FIG. 4 is a view focusing on the capping layer CPL and does not illustrate an actual relationship of layer thicknesses. As illustrated in FIG. 4, the capping layer CPL may include a hydrophilic material M2, and for example, may be composed of a plurality of layers including a hydrophilic layer L2 including the hydrophilic material M2 and a hydrophobic layer L3 including a hydrophobic material M3. When the water 20 penetrates from the outside to the inside of the light-emitting element 10, the water 20 reaches the uppermost hydrophilic layer L2 in the capping layer CPL through the defect of the sealing layer TFE. In the hydrophilic layer L2, the water 20 is captured by hydrogen-bonding with the hydrophilic material M2. This prevents or delays the penetration of water into layers below the uppermost hydrophilic layer L2. Next, when the uppermost hydrophilic layer L2 is saturated, the water 20 passes through the adjacent hydrophobic layer L3, reaches the second uppermost hydrophilic layer L2, and is captured. This is repeated until the lowermost hydrophilic layer L2 is saturated. Accordingly, as compared with the configuration of the comparative example, the present configuration example can also prevent or delay the deterioration of the light-emitting element 10.

The hydrophilic layer L2 and the hydrophobic layer L3 may be alternately stacked. The plurality of layers constituting the capping layer CPL include at least one set of the hydrophilic layer L2 and hydrophobic layer L3 pair, and preferably include a plurality of the pairs.

The hydrophobic layer L3 is preferably in contact with the second electrode E2. Thus, when the lowermost hydrophilic layer L2 captures water, the lowermost hydrophobic layer L3 can protect the second electrode E2 from the water. The hydrophilic layer L2 may be in contact with the sealing layer TFE.

The hydrophilic layer L2 and the hydrophobic layer L3 may have different refractive indices. The hydrophilic material M2 and the hydrophobic material M3 may have different refractive indices. When the difference in refractive index is used, it is possible to improve any one or more of the reflectance with respect to light incident from the light-emitting layer Em to the capping layer CPL, the light extraction efficiency from the light-emitting element 10, and the viewing angle characteristics of the light-emitting element 10.

The hydrophobic material M3 has a hydrophobic group. The hydrophobic material M3 may have, as a hydrophobic group, at least one selected from the group consisting of a linear alkyl group having 8 or more and 18 or less carbon atoms, a branched alkyl group having 8 or more and 18 or less carbon atoms, an alkylbenzene group having 6 or more and 16 or less carbon atoms, an alkylnaphthalene group, a perfluoroalkyl group having 4 or more and 9 or less carbon atoms, a polypropylene oxide group, and a polysiloxane group. The hydrophobic material M3 may include, for example, at least one selected from the group consisting of n-nonadecane, n-eicosane, n-heneicosane, n-docosane, n-tricosane, n-tetracosane, n-pentacosane, n-hexacosane, n-heptacosane, and n-octacosane.

The hydrophilic material M2 has a hydrophilic group. The hydrophilic material M2 may have, as a hydrophilic group, at least one selected from the group consisting of a hydroxyl group, a phosphate group, a carboxyl group, a sulfate group, a sulfo group, a pyridium group, a quaternary ammonium group, a fatty acid group, a primary alcohol group, a secondary alcohol group, a tertiary alcohol group, an ether group, a polyethylene oxide group, an amide group, and an amino group. The hydrophilic material M2 may include, for example, at least one selected from the group consisting of alcohol-based materials, fatty acid-based materials, polyvinyl alcohol, polyethyleneimine, polyacrylic acid, polyvinylpyrrolidone, polypropylene oxide, and polytetrahydrofuran.

Alternatively, the hydrophilic material M2 may include a metal salt that forms a hydrate. The metal salt preferably includes a non-hydrate at least at the time of manufacturing the light-emitting element 10. After manufacturing, the non-hydrate may react with water to be converted to a hydrate. Alternatively, after manufacturing, the hydrophilic material M2 may include a non-hydrate. The hydrophilic material M2 may include, for example, at least one selected from the group consisting of CaCl₂), CuSO₄, Na₂CO₃, MgCl₂, LiNO₃, Na₂SO₄, CH₃COONa, CaBr₂, Na₂HPO₄, Zn(NO₃)₂, Na₂S₂O₃, and Cd(NO₃)₂.

### Another Configuration Example of Capping Layer

The configuration of the light-emitting element 10 according to the disclosure is not limited to the above-described configuration examples 1 and 2, and the above-described configuration examples 1 and 2 may be combined, and various modifications may be made to each of the above-described configuration examples 1 and 2. The capping layer CPL according to the disclosure only needs to include at least one of the amphiphilic material M1 and the hydrophilic material M2.

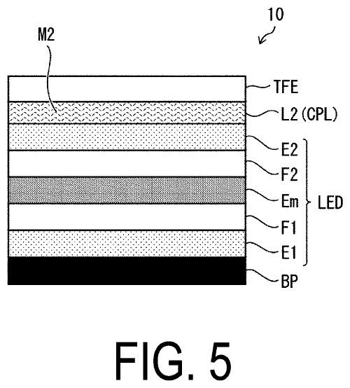

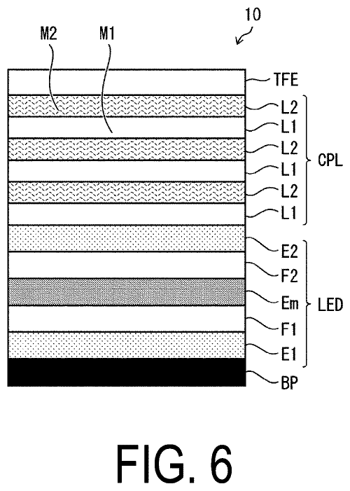

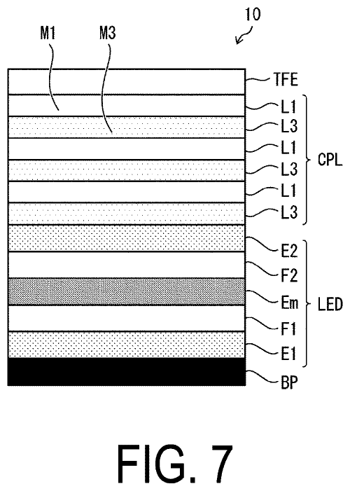

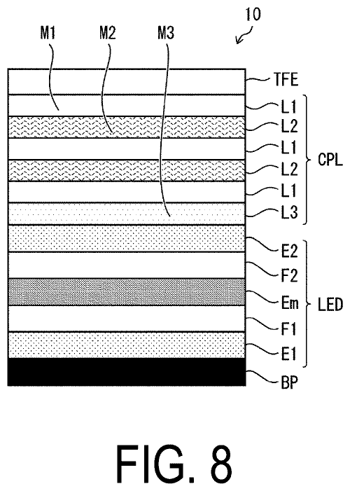

FIG. 5 to FIG. 8 are cross-sectional views each illustrating still another configuration example of the light-emitting element according to the embodiment of the disclosure. FIGS. 5 to 8 are views focusing on the capping layer CPL, and do not illustrate an actual relationship of layer thicknesses. As illustrated in FIG. 5, for example, the capping layer CPL may be composed of a single layer of the hydrophilic layer L2. As illustrated in FIG. 6, for example, the capping layer CPL may be composed of a plurality of layers including the amphiphilic layer L1 and the hydrophilic layer L2. As illustrated in FIG. 7, for example, the capping layer CPL may be composed of a plurality of layers including the amphiphilic layer L1 and the hydrophobic layer L3. As illustrated in FIG. 8, for example, the capping layer CPL may be composed of a plurality of layers including the amphiphilic layer L1, the hydrophilic layer L2, and the hydrophobic layer L3.

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

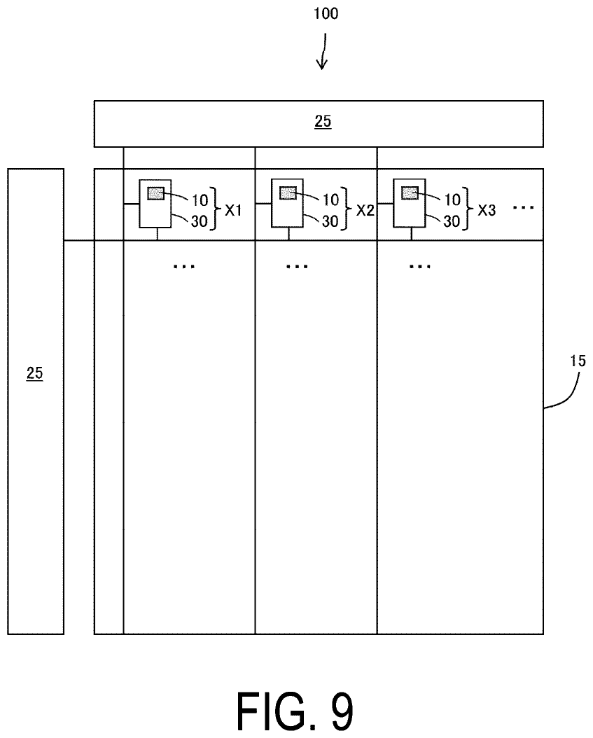

FIG. 9 is a plan view illustrating a configuration example of a display device according to an embodiment of the disclosure. As illustrated in FIG. 9, a display device 100 includes a first subpixel X1, a second subpixel X2, and a third subpixel X3. The first subpixel X1 includes a light-emitting element 10 that emits light of a first color and a pixel circuit 30 that controls the corresponding light-emitting element 10. The second subpixel X2 includes a light-emitting element 10 that emits light of a second color and a pixel circuit 30 that controls the corresponding light-emitting element 10. The third subpixel X3 includes a light-emitting element 10 that emits light of a third color and a pixel circuit 30 that controls the corresponding light-emitting element 10.

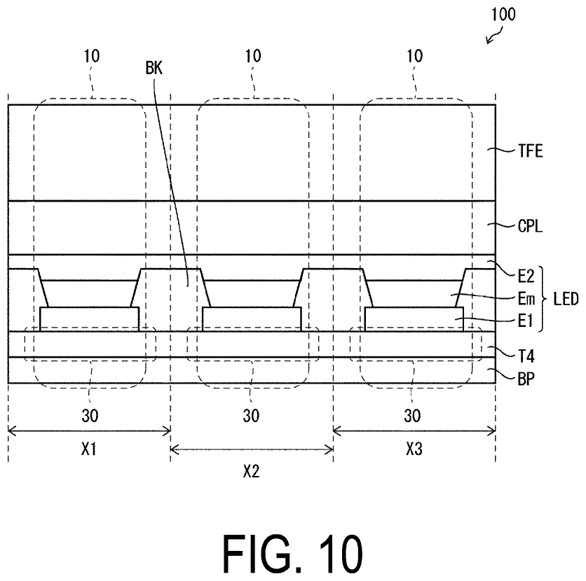

FIG. 10 is a cross-sectional view illustrating a configuration example of the display device according to the embodiment of the disclosure. As illustrated in FIG. 10, thicknesses of the capping layers CPL in the first subpixel X1, the second subpixel X2, and the third subpixel X3 may be uniform. In a case where the thicknesses are uniform, there is an advantage that the capping layers CPL in the respective subpixels can be formed in the same process.

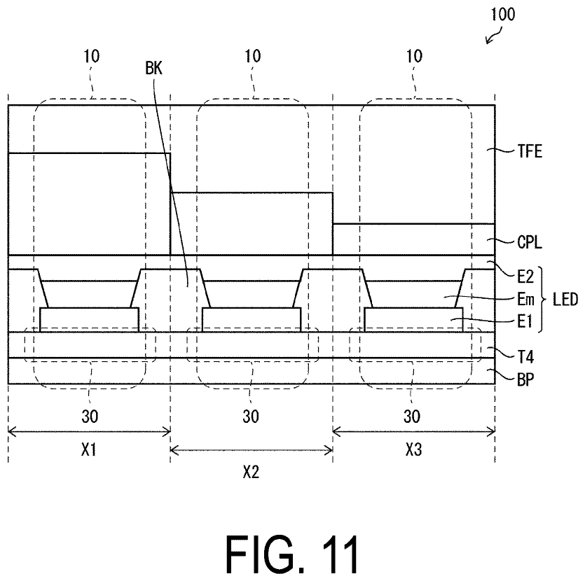

FIG. 11 is a cross-sectional view illustrating another configuration example of the display device according to the embodiment of the disclosure. As illustrated in FIG. 11, the thicknesses of the capping layers CPL in the first subpixel X1, the second subpixel X2, and the third subpixel X3 may be different from each other. In a case where the thicknesses are different from each other, there is an advantage that the thickness of the capping layer CPL in each subpixel can be designed depending on a wavelength of light in each subpixel. For example, when the first color is red, the second color is green, and the third color is blue, a thickness of the capping layer CPL in the first subpixel X1 may be greater than a thickness of the capping layer CPL in the second subpixel X2, and the thickness of the capping layer CPL in the second subpixel X2 may be greater than a thickness of the capping layer CPL in the third subpixel X3. In a case where the thicknesses are different from each other, one or two or more capping layers CPL may be shared by the first subpixel X1, the second subpixel X2, and the third subpixel X3.

As illustrated in FIG. 10 and FIG. 11, the display device 100 may include a thin film transistor layer T4 formed on the substrate BP, and the pixel circuit 30 may be formed in the thin film transistor layer T4 formed on the substrate BP. The display device 100 may include an edge cover film BK, and the edge cover film BK may cover edges of the first electrode E1.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A light-emitting element, comprising:
a first electrode;
a light-emitting layer located above the first electrode;
a second electrode located above the light-emitting layer;
a capping layer located on the second electrode, the capping layer comprising at least one of an amphiphilic material and a hydrophilic material; and
a sealing layer located on the capping layer.

2. (canceled)

3. (canceled)

4. The light-emitting element according to claim 1,
wherein the capping layer further comprises a plurality of layers including a hydrophilic layer having the hydrophilic material and a hydrophobic layer having a hydrophobic material.

5. The light-emitting element according to claim 4,
wherein the plurality of layers includes one or more pairs of the hydrophobic layer and the hydrophilic layer, and
the second electrode and the hydrophobic layer are in contact with each other.

6. The light-emitting element according to claim 4,
wherein the hydrophilic layer and the sealing layer are in contact with each other.

7. The light-emitting element according to claim 5,
wherein the plurality of layers further includes a plurality of the one or more pairs of the hydrophobic layer and the hydrophilic layer.

8. The light-emitting element according to claim 4,
wherein the hydrophobic layer and the hydrophilic layer have different refractive indices.

9. (canceled)

10. (canceled)

11. The light-emitting element according to claim 1, wherein the amphiphilic material includes a material in which a hydrogen in at least one selected from the group consisting of a hydrophobic hole injection, a transport material, a hydrophobic electron transport material, and a hydrophobic organic light-emitting material is substituted with a hydrophilic group.

12. The light-emitting element according to claim 1,
wherein the amphiphilic material includes a material in which a hydrogen in at least one selected from the group consisting of a carbazole derivative, a triarylamine derivative, and a dibenzothiophene derivative is substituted with a hydrophilic group.

13. The light-emitting element according to claim 1,
wherein the amphiphilic material includes a material in which a hydrogen in at least one selected from the group consisting of a phenanthrene derivative, a silole derivative, and a tris(8-quinolinolato)aluminum derivative is substituted with a hydrophilic group.

14. The light-emitting element according to claim 1,
wherein the amphiphilic material includes a material in which a hydrogen in at least one selected from the group consisting of an acene (polyacene) derivative, a quinacridone derivative, and a bisstyrylbenzene derivative is substituted with a hydrophilic group.

15. The light-emitting element according to claim 1,
wherein the amphiphilic material includes a material in which a hydrogen in at least one selected from the group consisting of a polyphenylene vinylene derivative, a polythiophene derivative, and a polyfluorene derivative is substituted with a hydrophilic group.

16. The light-emitting element according to claim 1,
wherein the amphiphilic material includes at least one selected from the group consisting of an alkylcarboxylic acid, a phosphatidylcholine, and a fluorescein.

17. The light-emitting element according to claim 4,
wherein the hydrophobic material includes at least one selected from the group consisting of a linear alkyl group having 8 or more and 18 or less carbon atoms, a branched alkyl group having 8 or more and 18 or less carbon atoms, an alkylbenzene group having 6 or more and 16 or less carbon atoms, an alkylnaphthalene group, a perfluoroalkyl group having 4 or more and 9 or less carbon atoms, a polypropylene oxide group, and a polysiloxane group.

18. The light-emitting element according to claim 4,
wherein the hydrophobic material includes at least one selected from the group consisting of an n-nonadecane, an n-eicosane, an n-heneicosane, an n-docosane, an n-tricosane, an n-tetracosane, an n-pentacosane, an n-hexacosane, an n-heptacosane, and an n-octacosane.

19. (canceled)

20. (canceled)

21. The light-emitting element according to claim 4,
wherein the hydrophilic material includes a metal salt that forms a hydrate.

22. The light-emitting element according to claim 21,
wherein the metal salt includes a non-hydrate.

23. The light-emitting element according to claim 4,
wherein the hydrophilic material includes at least one selected from the group consisting of CaCl₂), CuSO₄, Na₂CO₃, MgCl₂, LiNO₃, Na₂SO₄, CH₃COONa, CaBr₂, Na₂HPO₄, Zn(NO₃)₂, Na₂S₂O₃, and Cd(NO₃)₂.

24. The light-emitting element according to claim 1,
wherein the capping layer is thicker than the second electrode and is thinner than the sealing layer.

25. (canceled)

26. (canceled)

27. A display device comprising:
a first subpixel comprising the light-emitting element according to claim 1 that is configured to emit light of a first color;
a second subpixel comprising the light-emitting element according to claim 1 that is configured to emit light of a second color; and
a third subpixel comprising the light-emitting element according to claim 1 that is configured to emit light of a third color,
wherein the first color is red, the second color is green, and the third color is blue, and
a thickness of the capping layer in the first subpixel is greater than a thickness of the capping layer in the second subpixel, and the thickness of the capping layer in the second subpixel is greater than a thickness of the capping layer in the third subpixel.

28. The display device according to claim 27,
wherein thicknesses of the capping layers in the first subpixel, the second subpixel, and the third subpixel are uniform.

29. (canceled)

30. (canceled)
